(19) United States
(12) Patent Application Publication
(10) Pub. No.: US 2023/0185185 A1
(43) Pub. Date: Jun. 15, 2023

(54) METHOD AND APPARATUS FOR FORMING A BLANK MASK AND A LAYER FOR A BLANK MASK

(71) Applicant: SKC solmics Co., Ltd., Pyeongtaek-si (KR)

(72) Inventors: GeonGon LEE, Seoul (KR); Suk Young CHOI, Seoul (KR); Hyung-joo LEE, Seoul (KR); Suhyeon KIM, Seoul (KR); Sung Hoon SON, Seoul (KR); Seong Yoon KIM, Seoul (KR); Min Gyo JEONG, Seoul (KR); Hahyeon CHO, Seoul (KR); Taewan KIM, Seoul (KR); INKYUN SHIN, Seoul (KR)

(73) Assignee: SKC solmics Co., Ltd., Pyeongtaek-si (KR)

(21) Appl. No.: 18/081,019

(22) Filed: Dec. 14, 2022

(30) Foreign Application Priority Data
Dec. 15, 2021 (KR) 10-2021-0179502

(51) Int. Cl. G03F 1/60; G03F 7/20; G03F 1/32

(52) U.S. Cl. CPC G03F 1/60; G03F 7/70716; G03F 7/70808; G03F 1/32

(57) ABSTRACT

A method and apparatus for forming a layer including a light transmitting substrate, and a light shielding film disposed on the light transmitting substrate, and a phase shift film disposed between the light transmitting substrate and the light shielding film. A center measuring area based on the center of the light shielding film and an edge measuring area being distant by 20 mm from the edge of the light shielding film. The center measuring area and the edge measuring area are respectively squares having a side of 20 μm.

### CROSS-REFERENCE TO RELATED APPLICATION

This application claims the benefit under 35 USC 119(a) of Korean Patent Application No. 10-2021-00179502 filed on Dec. 15, 2021 in the Korean Intellectual Property Office, the entire disclosures of which are incorporated herein by reference for all purposes.

### TECHNICAL FIELD

The following description relates to a method and apparatus for forming a layer on a blank mask.

### DESCRIPTION OF RELATED ART

Due to high integration of semiconductor devices and the like, semiconductor devices require miniaturization of their circuit patterns. For this reason, the refinement and improvement of lithography techniques, which are techniques for developing a circuit pattern on a wafer surface using a photomask, are desired.

For developing a miniaturized circuit pattern, a light source of exposure used in an exposure process, such as in photolithography requires a short wavelength. In one example of a recent short wavelength light source, an argon fluoride (ArF) excimer laser (wavelength of 193 nm) has been employed.

A blank mask may include one of a light transmitting layer, a phase shift film, or a light shielding film formed on the light transmitting substrate. The light transmitting substrate may be manufactured through polishing and cleaning processes where first shaping and machining of a material having a light transmitting characteristic is performed.

In order to accomplish miniaturization of a circuit pattern developed on a wafer, it is necessary to prevent contamination and other manufacturing defects. These defects can include the occurrence of particles and a transcription of an undesired pattern. Other manufacturing goals include preventing non-uniformity in the roughness, thickness, transmittance, retardation, optical density, and the like in a manufacturing process of a blank mask. In some instances, the blank mask may have a quadrangle shape. In other embodiments, different blank mask shapes may be employed.

### SUMMARY

This summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a blank mask includes a light transmitting substrate, a light shielding film disposed on the light transmitting substrate, and a phase shift film disposed between the light transmitting substrate and the light shielding film. The blank mask includes a center measuring area based on the center of the light shielding film and an edge measuring area being distant by 20 mm from the edge of the light shielding film. The center measuring area and the edge measuring area are respectively squares having a side of 20 μm. The blank mask includes a center Rz roughness measured from the center measuring area, an edge Rz roughness measured from the edge measuring area, and an Rz roughness non-uniformity of 20% or less expressed by Equation 1-1 below:

Rz Roughness Non-uniformity=(Absolute Value of Difference between Center Rz Roughness and Edge Rz roughness/Center Rz Roughness)×100% [Equation 1-1]

The edge of the light shielding film may include four sides and the edge measuring area comprises four edge measuring areas being distant in equivalent intervals from two sides among the four sides.

A center Rsk roughness may be measured from the center measuring area, an edge Rsk roughness may be measured from the edge measuring area, and a Rsk roughness difference of 0.5 nm or less is expressed by Equation 1-2 below:

Rsk Roughness Difference=(Absolute Value of Difference between Center Rsk Roughness and Edge Rsk Roughness) [Equation 1-2]

A center Rku roughness may be measured from the center measuring area, an edge Rku roughness is measured from the edge measuring area, and a Rku roughness non-uniformity of 40% or less is expressed by Equation 1-3 below:

Rku Roughness Non-uniformity=(Absolute Value of Difference between Center Rku Roughness and Edge Rku Roughness/Center Rku Roughness)×100% [Equation 1-3]

The phase shift film may include a second center measuring area based on the center of the phase shift film and a second edge measuring area being distant by 20 mm from the edge of the phase shift film, a second center thickness measured from the second center measuring area, a second edge thickness measured from the second edge measuring area, and a thickness non-uniformity of 1.8% or less as expressed by Equation 2-1 below:

Thickness Non-uniformity=(Absolute Value of Difference between Second Center Thickness and Second Edge Thickness/Second Center Thickness)×100% [Equation 2-1]

The phase shift film may include a second center transmittance measured from the second center measuring area, a second edge transmittance measured from the second edge measuring area, and a transmittance non-uniformity of 5.2% or less as expressed by Equation 2-2 below:

Transmittance Non-uniformity=(Absolute Value of Difference between Second Center Transmittance and Second Edge Transmittance/Second Center Transmittance)×100% [Equation 2-2]

The phase shift film may include a second center retardation measured from the second center measuring area, a second edge retardation measured from the second edge measuring area, and a retardation non-uniformity of 1% or less as expressed by Equation 2-3 below:

Retardation Non-uniformity=(Absolute Value of Difference between Second Center Retardation and Second Edge Retardation/Second Center Retardation)×100% [Equation 2-3]

The light shielding film may include a center thickness measured from the center measuring area, an edge thickness measured from the second measuring area, and a thickness non-uniformity of 2% or less as expressed by Equation 1-4 below:

Thickness Non-uniformity=(Absolute Value of Difference between Center Thickness and Edge Thickness Difference/Center Thickness)×100% [Equation 1-4]

The light shielding film may include a center optical density measured from the center measuring area, an edge optical density measured from the edge measuring area, and an optical density non-uniformity of 2.7% or less as expressed by Equation 1-5:

Optical Density Non-uniformity=(Absolute Value of Difference between Center Optical Density and Edge Optical Density/Center Optical Density)×100% [Equation 1-5]

In another general aspect, an apparatus for forming a layer includes a chamber, a stage in which a target substrate is placed inside the chamber, a target unit comprising a raw material target for forming the target substrate, and a supplementary heater disposed to have an interval from the stage for heating the target substrate.

The target unit may be prepared to form the target substrate through DC sputtering or RF sputtering, the supplementary heater is being distant by a value of 50 mm to 250 mm from the side of the stage, and the stage and the target unit are rotatable.

The supplementary heater may be configured to heat the target substrate on the stage through heat radiation.

In another general aspect, a manufacturing method of a blank mask includes forming a phase shift film on a light transmitting substrate and forming a light shielding film on the phase shift film. The first film formation operation applies an electric power of 0.3 kW to 1.5 kW by the supplementary heater and the second film formation operation applies an electric power of 0.1 kW to 0.6 kW by the supplementary heater.

Other features and aspects will be apparent from the following detailed description, the drawings, and the claims.

### BRIEF DESCRIPTION OF THE DRAWINGS

FIG. 1 illustrates an example of an apparatus for forming a layer according to an embodiment;

FIG. 2 illustrates an example of a blank mask and a measuring area according to one or more embodiments.

FIG. 3 illustrates an example of a method 300 for forming a layer according to one or more embodiments.

Throughout the drawings and the detailed description, unless otherwise described or provided, the same drawing reference numerals will be understood to refer to the same elements, features, and structures. The drawings may not be to scale, and the relative size, proportions, and depiction of elements in the drawings may be exaggerated for clarity, illustration, and convenience.

### DETAILED DESCRIPTION

Hereinafter, while examples of the present disclosure will be described in detail with reference to the accompanying drawings, it is noted that examples are not limited to the same.

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of this disclosure. For example, the sequences of operations described herein are merely examples, and are not limited to those set forth herein, but may be changed as will be apparent after an understanding of this disclosure, with the exception of operations necessarily occurring in a certain order. Also, descriptions of features that are known in the art may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of this disclosure.

Throughout the specification, when an element, such as a layer, region, or substrate is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As used herein, the term “and/or” includes any one and any combination of any two or more of the associated listed items; likewise, “at least one of” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms, such as “above,” “upper,” “below,” “lower,” and the like, may be used herein for ease of description to describe one element's relationship to another element as shown in the figures. Such spatially relative terms are intended to encompass different orientations of the device in use or operation in addition to the orientation depicted in the figures. For example, if the device in the figures is turned over, an element described as being “above,” or “upper” relative to another element would then be “below,” or “lower” relative to the other element. Thus, the term “above” encompasses both the above and below orientations depending on the spatial orientation of the device. The device may also be oriented in other ways (rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes shown in the drawings may occur. Thus, the examples described herein are not limited to the specific shapes shown in the drawings, but include changes in shape that occur during manufacturing.

Herein, it is noted that use of the term “may” with respect to an example, for example, as to what an example may include or implement, means that at least one example exists in which such a feature is included or implemented while all examples are not limited thereto.

The features of the examples described herein may be combined in various ways as will be apparent after an understanding of this disclosure. Further, although the examples described herein have a variety of configurations, other configurations are possible as will be apparent after an understanding of this disclosure.

An objective of the present disclosure is providing a blank mask in which non-uniformity of the roughness, thickness, transmittance, retardation, optical density has been solved, which may be caused in a manufacturing process, a manufacturing device, and the like.

Another objective of the present disclosure is providing an apparatus for forming a layer in which a supplementary heater has been equipped, and a blank mask in which the uniformity of properties has been secured through the above.

Another objective of the present disclosure is proving a blank mask that does not have a great difference in the properties between an edge area and a center area because a thermal distribution is uniformly regulated during film formation. Accordingly, embodiments of the present disclosure can easily form a minute circuit pattern when the blank mask is manufactured via a photomask to create circuit patterns thereon.

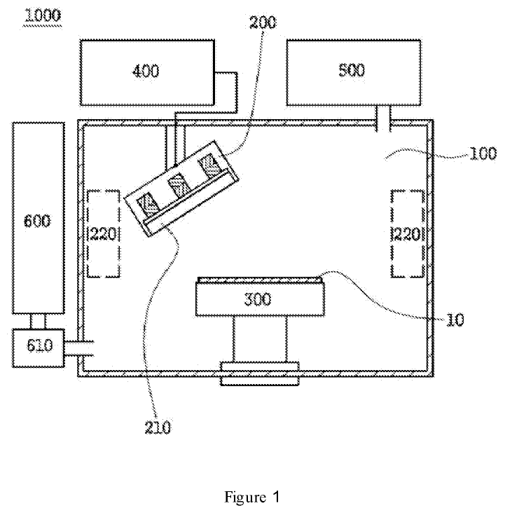

As illustrated in FIG. 1, an example of an apparatus 1000 for forming a layer on a blank mask according to an embodiment is illustrated and may include a chamber 100. In one embodiment, there may be a stage 300 provided in the chamber 100. In some embodiments, the stage is the portion of apparatus 1000 on which a target substrate 10 is to be formed. The chamber 100 can allow an enclosed space to control the environment for forming layers on the blank mask.

In an embodiment of the apparatus 1000, a target unit 200 including a raw material 210 for forming the target substrate 10 is provided within the chamber 100. Within the chamber, at least one supplementary heater 220 is disposed apart from the stage. In some embodiments, two or more heaters 220 can be provided, as illustrated for example, in apparatus 1000 of FIG. 1. The supplementary heater 220 can achieve a uniformity in film formation overall when a phase shift film or a light shielding film is formed on a target substrate.

In some embodiments, the target substrate 10 may start as a light transmitting substrate when a phase shift film is formed. The target substrate 10 may be a laminate including a phase shift film formed on the light transmitting substrate when a light shielding film is formed.

In one embodiment, the target unit 200 can promote the formation of a film made from a raw material on the target substrate 10 through DC sputtering or RF sputtering. In additional embodiments, the stage 300 may be configured to rotate at varying speeds to enhance the formation of the film on the target substrate 10. The target unit 200 may also include the raw material 210 which is provided at one end, and the raw material 210 may be a source for the material that makes up the sputtering application. In addition, the target unit 200 can include a raw material 210 that includes a phase shift film for forming one layer and another raw material for forming a light shielding film.

In one embodiment, the stage 300 may hold the target substrate 10 to rotate the substrate 10 at a desired speed.

In one embodiment, a shortest distance T/S between the raw material target 210 of the target unit 200 and a target substrate 10 placed in the stage 300 may be approximately 150 mm to 400 mm, or in another embodiment, 200 mm to 350 mm.

The supplementary heater 220 may be placed a length of 50 mm to 250 mm, in one embodiment, or 70 mm to 150 mm, in another embodiment, from one side of the stage 300 having the shortest distance. As illustrated in FIG. 1, there may be one or more supplementary heaters 220 may be equipped having an equivalent distance from one side and from the other side of the stage.

The supplementary heater 220 may heat a target substrate 10 on the stage 300 by emitting heat radiation. In one embodiment, the supplementary heater 220 may be an infrared heater having an electric power of 0.1 kW to 1.5 kW. The supplementary heater 220 may have a conversion efficiency of 60% to 85% for heat radiation energy compared to the electric power supplied thereto.

In one embodiment, the apparatus 1000 may include a power source 400 that supplies an electric power to the target unit 200. In additional embodiments, the apparatus 1000 may include a vacuum pump 500 for a degassing operation to remove gases from the chamber 100. In other embodiments, the vacuum pump 500 can form a vacuum in the chamber 100 by removing all or most gases therefrom.

The apparatus 1000 may also include a gas storage unit 600 where a gas to be inserted into the chamber 100 during the film formation is stored. The apparatus 1000 may also include a flow adjustment unit 610 for adjusting the amount of flow of a gas within and to the chamber 100. In some examples, the gas storage unit 600 can provide storage for and delivery of one or more gases as required.

In one or more embodiments, the light transmitting substrate may be made from a material having a light transmitting characteristic with respect to exposure light with wavelengths of 172 nm, 193 nm, and 248 nm and a light source of xenon (Xe₂), argon fluoride (ArF), krypton fluoride (KrF), or the like. Soda lime, quartz glass, or calcium fluoride may be applied to the light transmitting substrate, and for example, quartz glass may be applied.

In one or more embodiments, light transmitting substrate may have a transmittance of at least 85% or more and less than or equal to 100% with respect to a laser with the wavelength of 193 nm having a light source of argon fluoride (ArF).

In one or more embodiments, the phase shift film may be a thin film which attenuates the strength of an exposure light to be transmitted. The phase shift film can also regulate a retardation, and thereby substantially suppress a diffraction of light generated at an edge of a pattern of a photomask. In addition, a light shielding film can effect a blocking of an unwanted exposure of light to thereby helps the formation of a pattern.

In one or more embodiments, the phase shift film may be formed of molybdenum, and can also include any one or more elements selected from the group consisting of silicon, nitrogen, oxygen, and carbon, and for example, may comprise MoSi, MoSiN, MoSiO, MoSiC, MoSiCN, MoSiCO, MoSiON, MoSiCON, or the like.

In one or more embodiments where the phase shift film includes at least MoSi, the phase shift film may include molybdenum in an amount of 0.001% to 10% and may also include silicon in an amount of 20% to 99%. In yet another embodiment, the phase shift film may also include nitrogen in an amount of 0.001% to 65%, oxygen in an amount of 0.1% to 35%, and carbon in an amount of 0.001% to 15%. The phase shift film may have a thickness of about 15 nm to 90 nm.

Additionally, the phase shift film may have a transmittance value of 1% to 30%, or a transmittance value of 3% to 10% with respect to a laser with the wavelength of 193 nm and a light source of argon fluoride (ArF). Additionally, the phase shift film may have a retardation of 170° to 190°, or 175° to 185° with respect to a laser having a wavelength of 193 nm and a light source of argon fluoride (ArF). In such a case, when the laminate for a blank mask is utilized as a photomask, the resolution may be improved.

In one or more embodiments, edges of the phase shift film may be composed of four sides, and may comprise a quadrangle shape.

The phase shift film may have a second center measuring area and a second edge measuring area being distant by 20 mm from the edge of the phase shift film.

The center of the phase shift film may be the center of gravity of the phase shift film. For example, the figure of a ground plan of the phase shift film viewed at an upper position may be a shape composed of four sides, and the center may be the center of gravity of the shape. When considering the center as a reference, the center refers to the center of a measuring area and the center of the phase shift film which are designed to be the same position.

In addition, the second edge measuring area may be four second edge measuring areas being distant by the same interval from two sides among the four sides. For example, from the upper side, lower side, left side and right side, one being distant by the same interval from the upper side and the left side, one being distant by the same interval from the upper side and the right side, one being distant by the same interval from the left side and the lower side, and one being distant by the same interval from the lower side and the right side may be considered the four second edge measuring areas.

From the phase shift film, properties are measured from the second center measuring area and the second edge measuring area to judge uniformity. When a plurality of second edge measuring areas are present, the average of properties measured from the second edge measuring area may be considered as properties of the second edge measuring area.

The phase shift film may have a second center thickness measured from the second center measuring area, and may have a second edge thickness measured from the second edge measuring area.

The phase shift film may have a thickness non-uniformity of 1.8% or less, 1.2% or less, or 0.8% or less as expressed by Equation 2-1 below. The thickness non-uniformity may be 0.1% or more.

Thickness Non-uniformity=(Absolute Vale of Difference between Second Center Thickness and Second Edge Thickness/Second Center Thickness)×100% [Equation 2-1]

In one or more embodiments, the phase shift film may have a difference of 12 Å or less, 8 Å or less, 4.8 Å or less between the second center thickness and the second edge thickness. The difference of thickness may be 0.1 Å or more.

In one or more embodiments, the phase shift film may have the above described thickness non-uniformity which can minimize the difference in the thickness for the center portion and the edge portion of the phase shift film, in addition to securing a good quality when a subsequent light shielding film is formed.

In one or more embodiments, the phase shift film may also have a second center transmittance measured from the second center measuring area, and may have a second edge transmittance measured from the second edge measuring area.

The phase shift film may have a transmittance non-uniformity of 5.2% or less, 4.8% or less, or 4.5% or less as expressed by Equation 2-2 below. In addition, the transmittance non-uniformity may be 0.1% or more.

Transmittance Non-uniformity=(Absolute Value of Difference between second Center Transmittance and Second Edge Transmittance/Second Center Transmittance)×100% [Equation 2-2]

In one or more embodiments, the phase shift film may have a difference of 0.33% or less, 0.3% or less, or 0.28% or less between the second center transmittance and the second edge transmittance. The difference of transmittance could be 0.05% or more.

In one or more embodiments, the phase shift film may have a transmittance non-uniformity as described above which can minimize a difference in the transmittance for the center portion of the phase shift film and the transmittance for the edge portion Accordingly, a blank mask and a photomask manufactured through the same process can secure good quality.

In one or more embodiments, the phase shift film may have a second center retardation measured from the second center measuring area, and may have a second edge retardation measured from the second edge measuring area.

The phase shift film may have a retardation non-uniformity of 1% or less, 0.8% or less, or 0.44% or less expressed by Equation 2-3. The retardation non-uniformity may be 0.01% or more.

Retardation Non-uniformity=(Absolute Value of Difference between Second Center Retardation and Second Edge Retardation/Second center Retardation)×100% [Equation 2-3]

In one or more embodiments, the phase shift film may have a difference of 2.4° or less, 1.6° or less, or 0.76° or less between the second center retardation and the second edge retardation. The difference of retardation may be 0.1° or more.

Where the phase shift film has a retardation non-uniformity as discussed above, the phase shift film can thereby minimize a difference in retardation for the center portion of the phase shift film and the edge portion of the phase shift film, and a blank mask and a photomask manufactured through the same exemplary process can secure good quality.

The thickness of the phase shift film may be calculated through a photograph obtained by Transmission Electron Microscope (TEM) from each measuring area, and the transmittance and the retardation may be measured through a retardation/transmittance meter (e.g., MG-Pro available from Nano-View). These processes are described in Experiment Example below.

In one or more embodiments, the light shielding film may include a transition metal from any one or more selected from a group including chrome, tantalum, titanium, and hafnium, and one or more non-metal elements selected from the group including oxygen, nitrogen, and carbon.

The light shielding film may also include any one or more selected from the group including CrO, CrON, CrOCN, and combinations thereof.

In one or more embodiments, the light shielding film may have a multilayer structure, or, in another embodiment, the light shielding film may have a bilayer structure. For example, the upper layer of the light shielding film may be formed to allow oxygen or nitrogen to have an increased amount in the surface direction of the light shielding film, in order to control the surface strength of the light shielding film and the like. The remaining portion of the light shielding film excluding the surface layer is referred to as a lower layer of the light shielding film, in order to distinguish it from the surface layer of the shading layer.

In one or more embodiments, the surface layer of the light shielding film may have a thickness of 30 nm to 80 nm, or 40 nm to 70 nm.

In one or more embodiments, the lower layer of the light shielding film to the surface layer of the light shielding film may have a thickness ratio of 1:0.02 to 0.25, or 1:0.04 to 1:0.18.

In one or more embodiments, the lower layer of the light shielding film may include the transition metal in an amount of 30% to 47%, or 35.5% to 42%.

In one or more embodiments, the lower layer of the light shielding film may include the transition metal in an amount of 30% to 47%, or 35.5% to 42%

In one or more embodiments, the lower layer of the light shielding film may include oxygen and nitrogen in an amount of 38% to 52% and 42.5% to 47.5%, respectively.

In one or more embodiments, the lower layer of the light shielding film may include oxygen in an amount of 28% to 45% or 33% to 42%.

In one or more embodiments, the lower layer of the light shielding film may include nitrogen in an amount of 5% to 16%, or 8% to 13%.

In one or more embodiments, the lower layer of the light shielding film may also include carbon. The lower layer of the light shielding film may include carbon in an amount of 10% to 20%, or 14% to 15.5%.

In one or more embodiments, the upper layer of the light shielding film may include the transition metal in an amount of 50% to 65%, or 52% to 60%.

In one or more embodiments, the upper layer of the light shielding film may include the oxygen and nitrogen in an amount of 18% to 45% or 21% to 41%.

In one or more embodiments, the upper layer of the light shielding film may include oxygen in an amount of 7% to 24% or 10% to 21%.

In one or more embodiments, the upper layer of the light shielding film may include nitrogen in an amount of 8% to 30%, or 11% to 25%.

In one or more embodiments, the upper layer of the light shielding film may further include carbon. The upper layer of the light shielding film may include carbon in an amount of 3.5% to 18% or 6.5% to 15%.

In one or more embodiments, the light shielding film may have a reflectance of about 35% or less, or about 30% or less with respect to a laser having a wavelength of 193 nm and a light source of argon fluoride (ArF). The reflectance may be about 20% or more, about 23% or more, or about 25% or more.

The edge of the light shielding film may be composed of four sides and may form a same quadrangle shape as the phase shift film.

The light shielding film may have a center measuring area based on the center and an edge measuring area being distant by 20 mm from the edge of the light shielding film.

For example, in one or more embodiments, the center of the light shielding film may be a center of gravity of the phase shift film. For example, the figure of a ground plan of the light shielding film when viewed at an upper position may be a shape including four sides, and the center may be the center of gravity of that shape. When considering the center as a reference point, the center refers to the center of a measuring area and the center of the light shielding film which are designed to be the same position.

In an addition example, the edge measuring area may be four second edge measuring areas being distant by the same interval from two sides among the four sides. For example, from the upper side, lower side, left side and right side, one being distant by the same interval from the upper side and the left side, one being distant by the same interval from the upper side and the right side, one being distant by the same interval from the left side and the lower side, and one being distant by the same interval from the left side and the right side may be the four second edge measuring areas.

In one or more embodiments, from the light shielding film, these properties are measured from the center measuring area and the edge measuring area to judge uniformity. When the plural second edge measuring areas are present, the average of properties measured from the edge measuring area may be considered as properties of the edge measuring area.

In one or more embodiments, the light shielding film may have a center Rz roughness measured from the center measuring area, and may have an edge Rz roughness measured from the edge measuring area.

In one or more embodiments, the light shielding film may have an Rz roughness non-uniformity of 20% or less, 12% or less, 10% or less, or 8.2% or less as expressed by Equation 1-1 below. The Rz roughness non-uniformity may be 0.01% or more, 0.1% or more, or 0.3% or more.

Rz Roughness Non-uniformity=(Absolute Value of Difference between Center Rz Roughness and Edge Rz Roughness/Center Rz Roughness)×100% [Equation 1-1]

Thus, in one or more embodiments, the light shielding film may have an Rz roughness difference of 1.5 nm or less, 0.8 nm or less, or 0.54 nm or less between the center Rz roughness and the edge Rz roughness. The Rz roughness difference may be 0.001 nm or more, or 0.01 nm or more.

The light shielding film having such an Rz roughness non-uniformity can minimize an Rz roughness difference between the center portion and the edge portion of the light shielding film, and can improve efficiency of subsequent cleaning processes. A photomask manufactured through the same method can show a thickness uniformity overall to secure a good quality, and can minimize a transcription of an undesired pattern.

The light shielding film may have a center Rsk roughness measured from the center measuring area, and may have an edge Rsk roughness measured from the edge measuring area.

The light shielding film may have an Rsk roughness difference of 0.5 nm or less, 0.4 nm or less, or 0.34 nm or less between the center measuring area and the edge measuring area expressed by Equation 1-2 below. The Rsk roughness difference may be 0.001 nm or more, or 0.01 nm or more.

Rsk roughness difference=(Absolute Value of Difference between Center Rsk Roughness and Edge Rsk Roughness) [Equation 1-2]

Accordingly, where the light shielding film has the above described Rsk non-uniformities, it can minimize its Rsk roughness value between the center portion and the edge portion of the light shielding film, and a photomask manufacture through the same method and apparatus can secure a good quality.

The light shielding film may have a center Rku roughness measured from the center measuring area, and may have an edge Rku roughness measured from the edge measuring area.

The light shielding film may have an Rku roughness non-uniformity of 40% or less, 33% or less, or 28.5% or less. The Rku roughness non-uniformity may be 0.01% or more, 0.1% or more, or 0.5% or more.

Rku Roughness Non-uniformity=(Absolute Value of Difference between Center Rku Roughness and Edge Rku Roughness/Center Rku Roughness)×100% [Equation 1-3]

In one or more embodiments, the light shielding film may have an Rku roughness difference of 1.3 nm, 1.0 nm or less, or 0.67 nm or less between the center Rku roughness and the edge Rku roughness. The Rku roughness value may be 0.001 nm or more, or 0.01 nm or more.

When the light shielding film has an Rku roughness non-uniformity as described above, it can minimize the Rku roughness difference between the center portion and the edge portion of the light shielding film, and a photomask manufactured through the same method or apparatus can secure a good quality.

The Rz, Rsk and Rku roughness values may be respectively measured through roughness meter (PPP-NHCHR available from Park System) at the measuring areas, respectively. The thickness thereof may be calculated through a photograph obtained by Transmission Electron Microscope (TEM) at the measuring areas, respectively. The optical density may be measured through a spectroscopic ellipsometer (MG-Pro available from Nano-View corporation). The process was described in Experiment Examples below.

The light shielding film may have a center thickness measured from the center measuring area, and may have an edge thickness measured from the edge measuring area.

In some examples, the light shielding film may have a thickness non-uniformity of 2% or less, 1.5% or less, or 1.1% or less expressed by Equation 1-4 below. The thickness non-uniformity may be 0.05% or more.

Thickness Non-uniformity=(Absolute Value of Difference between Center Thickness and Edge Thickness/Center Thickness)×100% [Equation 1-4]

The resulting light shielding film may have a difference of 10 Å or less, 7 Å or less, 5.7 Å or less between the center thickness and the edge thickness. The difference of the thickness may be 0.1 Å or more.

The light shielding film having the above described thickness non-uniformity can thereby minimize the difference in the thickness for the center portion and the edge portion of the light shielding film, and a photomask manufactured through the same methods and apparatus can secure a good quality.

In one or more embodiments, the light shielding film may have a center optical density measured from the center measuring area, and may have an edge optical density measured from the edge measuring area.

The light shielding film may have an optical density non-uniformity of 2.7% or less, 2.0% or less, or 1.3% or less expressed by Equation 1-5 below. The optical density non-uniformity may be 0% or more, or 0.05% or more.

Optical Density Non-uniformity=(Absolute Value of Difference between Center Optical Density and Edge Optical Density/Center Optical Density)×100% [Equation 1-5]

In one or more embodiments, the light shielding film may have a difference of 0.04 or less, 0.03 or less, or 0.025 or less between the center optical density and the edge optical density. The difference of the optical density may be 0 or more, or 0.001 or more.

The light shielding film has such an optical density non-uniformity as described above, and examples thereof can minimize a difference in the optical density for the center portion and edge portion of the light shielding film, and a photomask manufactured through the same method can secure a good quality.

Accordingly, in various embodiments, the blank mask can achieve a property of being uniform overall through a specific thermal treatment which may prevent an undesired pattern from being transcribed in an exposure process. In addition, the blank mask may be applied as a photomask in a process of forming an integrated circuit pattern having a high quality.

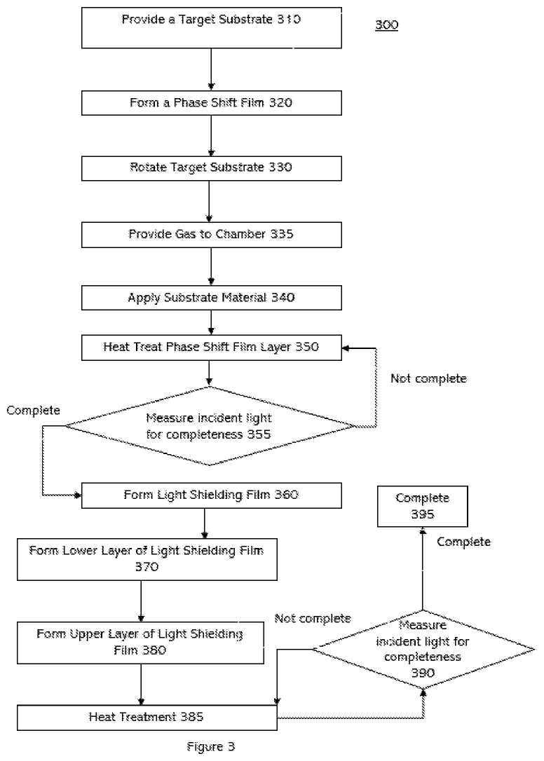

Referring to FIG. 3, a method 300 of manufacturing a blank mask according to an embodiment is illustrated. The method 300 can be implemented in one or more embodiments of the apparatus 1000 shown in FIG. 1. At Step 310, a target substrate 10 is provided. In one or more embodiments, the target substrate 10 is provided on stage 300 in apparatus 1000 as illustrated, for example, in FIG. 1. In one embodiment, the target substrate 10 may be a light transmitting substrate. Next, in Step 320, a phase shift film is formed on the light transmitting substrate. As discussed later, in Step 360, a light shielding film is then formed on the completed phase shift film. In some embodiments, in Step 350, the forming of the phase shift film can include a heating step that includes applying an electric power of 0.3 kW to 1.5 kW by the supplementary heater 220. In some examples, the supplementary heater may be employed to apply heat resulting from an electric power of 0.1 kW to 0.6 kW supplied by the source 400.

In one or more embodiments, at Step 340 the phase shift film may be formed on the light transmitting substrate through a sputtering application, or the like. The sputtering process may include DC sputtering or RF sputtering. In some examples, the sputtering of Step 340 is performed by target unit 200 of FIG. 1.

In one or more embodiments, the raw material 210 of the target unit 200 may include molybdenum and silicon. In some examples, the target unit 200 may include Mo in an amount of 5% to 20%, Si in an amount of 70% to 97%, carbon in an amount of 50 ppm to 230 ppm, and oxygen in an amount of 400 ppm to 800 ppm.

In one or more embodiments of method 300, the shortest distance between the raw material 210 and the target substrate 10 of the target unit 200 may have a length of 150 mm to 400 mm, or 200 mm to 350 mm.

In one or more embodiments of method 300, the raw material 210 of the target unit 200 may be disposed to lean by an angle of 10 degrees to 40 degrees from the target substrate.

In one or more embodiments of method 300, the target unit 200 may also be rotated as illustrated in Step 330 where the rotation speed of the target unit 200 may be set to a speed between 50 rpm and 250 rpm. An rpm of the target unit 200 may be a value of 80 rpm to 120 rpm which can be increased at desired rate to the maximum rpm discussed above. In one example, the rotation speed may be increased to be a value of 130 rpm to 250 rpm as the maximum rpm at a rate of 8 rpm/min to 12 rpm/min. The rotational speed of the target unit 200 can help increase uniformity when forming a layer. Thus, the target unit 200 may rotate during the application of the substrate material in Step 340.

In one or more embodiments, the target unit 200 may also provide a magnetic field of 10 mT to 100 mT.

As discussed above, in Step 350, the supplementary heater 220 may radiate heat to the surface of a target substrate 200 from a distance of 40 mm to 250 mm. In another example, a distance of 70 mm to 150 mm may be considered the shortest distance from the side of the stage 300.

In Step 310, the supplementary heater 220 may have a different electric power ranges. In some examples, the power range can include 0.3 kW to 1.5 kW, 0.3 kW to 1.2 kW, or 0.4 kW to 1.0 kW. In some embodiments, these electric power ranges and intervals can improve uniformity forming a phase shift film on the target substrate 200.

As discussed above in Step 330, the stage 300 may be rotated at a certain speed. For example, the stage 300 may be rotated in a speed of 2 rpm to 50 rpm, or 5 rpm to 20 rpm. When having such an rpm, uniformity of the phase shift film may be increased further.

During the forming of the phase shift film of Step 320, in some embodiments, in Step 335, an input gas is injected into the chamber 100. In one or more embodiments, the input gas may include a sputtering gas such as argon, and a reactive gas comprising nitrogen, oxygen, carbon monoxide, carbon dioxide, nitrous oxide, nitric oxide, nitrogen dioxide, ammonia, methane, and the like. In some embodiments, the reactive gas may include for example, nitrogen and oxygen. In some embodiments, the providing of gas to the chamber of Step 335 can be performed by the flow adjustment unit 610 to provide gases from the gas storage unit 600 of FIG. 1.

During the applying of the substrate material 340, in some embodiments a vacuum may be drawn in the chamber 100. In some instances, the vacuum may be between 10⁻⁴ Pa and 10⁻¹ Pa. When such a vacuum degree is applied, an acceleration energy of particles to be sputtered can be properly adjusted and stability of forming a layer can be secured. In one or more embodiments, the vacuum may be drawn by vacuum pump 500 of FIG. 1.

In Step 335 when the gas is provided to the chamber 100, the input gas may be provided in a variety of gases having a ratio of, for example, argon in an amount of 5% to 20%, nitrogen in an amount of 42% to 62%, and helium in an amount of 28% to 48% compared to 100% as the whole based on the volume.

In one or more embodiments of Step 340, the sputtering gas may have a flow amount of 5 sccm to 100 sccm, 50 sccm or less, or 20 sccm or less. The reactive gas may have a flow amount of 5 sccm to 200 sccm, or 150 sccm or less.

The first operation for forming the phase shift film of Step 320 may proceed until Step 355 determines if the phase shift film is complete when, in one embodiment, the photon energy (PE) of an incident light at a point having Del_1 value of 0 expressed by Equation 1 below reaches any one eV value of 1.5 eV to 3.0 eV.

$$Del\_ 1 = {lim}_{Δ PE \to 0} ( \frac{Δ DPS}{Δ PE} ) \qquad [ Equation 1 ]$$

In the Equation 1, the DPS value is any one value between following i) and ii).

In the measurement for the surface of the phase shift film by a spectroscopic ellipsometer with an incident angle applied to be 64.5°, i) when the retardation between P wave and S wave of a reflection light is 180° or less, the DPS value is a retardation between the P wave and S wave, or ii) when the retardation between P wave and S wave of a reflection light is more than 180° or more, the DPS value is a value of subtracting the retardation between the P wave and S wave from 360°.

The incident angle may be an angle made by an incident light of a spectroscopic ellipsometer and a normal line of a phase shift film.

The measurement through the spectroscopic ellipsometer may be made for example, by a MG-Pro model available from Nano-View corporation. In the fixed incident angle during the measurement, the photon energy value of the incident light may be set to be a relatively high or low scope to measure the distribution of retardation between P wave and S wave of a reflection light, and thereby the optical properties of upper and lower layers of the formed film.

Method 300 may also include, in one or more embodiments, a thermal treatment as shown in Steps 350 and Step 385. In the heat treatment of Steps 350 and 385, a laminate of a phase shift film and a light transmitting substrate are thermally treated.

In one or more embodiments, in Step 350 a first exemplary operation for thermal treatment may be made inside a separate chamber for a first thermal treatment process, or may be made inside the chamber 100 where a film has been formed. For example, heating may proceed to reach a temperature of 300° C. to 600° C. in a heating speed of 5° C./min to 80° C./min, and thermal treatment may proceed for a time of 20 minutes to 120 minutes at the maximum temperature after heating. After the thermal treatment, natural cooling may be made, and subsequently, nitrogen (N₂) gas at 300° C. may be introduced into the chamber in a flow amount of 0.1 slm to 10 slm.

In one or more embodiments, after Step 355 has measured the phase shift film layer is complete, a second operation in Step 360 for forming a light shielding film on a phase shift film may proceed.

In the second operation for forming a layer of Step 360, a light shielding film may be formed on the phase shift film on the light transmitting substrate in a method of sputtering and the like. The sputtering may include a DC sputtering, or an RF sputtering.

In the second operation for forming a layer of Step 360, a raw material for the targe unit 200 may mainly comprise one transition metal selected from the group consisting of chrome, tantalum, titanium, and hafnium, and may comprise chrome.

In one or more embodiments, the shortest distance between the raw material 210 of the target unit 200 of the second operation for forming a layer may have a length of 150 mm to 400 mm, or 200 mm to 350 mm.

The raw material 210 of the target unit 200 in the second operation for forming a layer may be disposed to lean by an angle of 10 degrees to 40 degrees from the target substrate where the phase shift film has been formed.

In the second operation for forming a layer of Step 360, for example, the target unit 200 may be rotated at a rotation speed of 50 rpm to 250 rpm. The initial rpm may be a value of 80 rpm to 120 rpm, and may be gradually increased in a certain speed to reach the maximum rpm. The rotation speed may be increased to reach a value of 130 rpm to 250 rpm as the maximum rpm in a speed of 8 rpm/min to 12 rpm/min. Having such a speed may help improve a uniformity when forming a layer.

In the second operation for forming a layer of Step 360, the supplementary heater 220 may likewise radiate heat to the surface to be formed in Step 385, in the state of being distant by a length of 50 mm to 250 mm, or 70 mm to 150 mm from the side of the stage 300 as the shortest distance.

In the second operation for forming a layer of Step 360, the supplementary heater 220 may have an electric power of 0.1 kW to 1.0 kW, 0.15 kW to 0.8 kW, or 0.25 kW to 0.5 kW. When having such an electric power and an interval, uniformity can be effectively maintained in the formation of a light shielding film on a phase shift film.

In the second operation for forming a layer of Step 360, the stage 300 may be rotated in a certain speed, similar to Step 330 for the first layer, for example, the rotation speed may be a rate of 2 rpm to 50 rpm, or 5 rpm to 20 rpm. By having such an rpm, a uniformity of the light shielding film may be further increased.

In the second operation for forming a layer of Step 360, a similar process as that of Step 335 for the first layer may be applied where an input gas is injected into the chamber 100. The input gas may include a sputtering gas such as argon, and a reactive gas comprising nitrogen, oxygen, carbon monoxide, carbon dioxide, nitrous oxide, nitric oxide, nitrogen dioxide, ammonia, methane, and the like, wherein the reactive gas may comprise for example, nitrogen and oxygen.

In the second operation for forming a layer of Step 360, the chamber 100 may have a vacuum applied thereto to institute a vacuum to a degree of 10⁻⁴ Pa to 10⁻¹ Pa. In such a vacuum degree, the acceleration energy of particles to be sputtered can be properly adjusted and stability of forming a layer can be secured.

The second operation for forming a layer of Step 360 may be segmented into a process of forming a lower layer of the light shielding film in Step 370 and a process of forming an upper layer of the light shielding film in Step 380. That is, the light shielding film being formed in the operation of Step 360 may include one or more layers.

In Step 370 where the lower layer of the light shielding film of the second operation of Step 360 is formed, the input gas may be provided in a ratio having argon in an amount of 14% to 24%, nitrogen in an amount of 7% to 15%, helium in an amount of 29% to 39%, and carbon dioxide in an amount of 32% to 42% compared to 100% as the whole based on the volume.

In the process of forming an upper layer of the light shielding film of Step 380 of the second operation for forming a layer of Step 360, the input gas may be provided in a ratio having argon in an amount of 14% to 24%, nitrogen in an amount of 7% to 15%, helium in an amount of 29% to 39%, and carbon dioxide in an amount of 32% to 42%.

In Step 380, the input gas may be provided in a ratio having argon in an amount of 47% to 67% and nitrogen in an amount of 33% to 53% compared to 100% as the whole based on the volume.

In the second operation for forming a layer of Step 360, the sputtering gas may have a flow amount of 5 sccm to 100 sccm, 50 sccm or less, or 20 sccm or less. The reactive gas may have a flow amount of 5 sccm to 200 sccm, or 150 sccm or less.

In Step 370, in the forming of the lower layer of the light shielding film of the second operation for forming a layer of Step 360 may proceed until Step 390 when it is determined whether a photon energy of an incident light reaches to any one eV value of 1.4 eV to 2.4 eV, at a point having the retardation of 140° between P wave and S wave of a reflection light measured by a spectroscopic ellipsometer.

In Step 380, the forming of the upper layer of the light shielding film of the second operation for forming a layer of Step 360 may likewise proceed until a photon energy of an incident light reaches to any one eV value of 2.25 eV to 3.25 eV, at a point having the retardation of 140° between P wave and S wave of a reflection light measured by a spectroscopic ellipsometer.

In the process of forming the second films of Step 360, in Step 385 a heat treatment may be provided, which thermally treats a laminate of light shielding film/phase shift film/light transmitting substrate which was applied through Step 360 in one example, and through Steps 370 and 380, in another example of method 300.

The second operation for thermal treatment of Step 385 may be made inside a separate chamber for a thermal treatment process, or may be made inside the chamber where the layer was formed. For example, thermal treatment may proceed for a time of 5 minutes to 60 minutes at a temperature of 100° C. to 500° C. After the thermal treatment, natural cooling may be operated, and cooling may proceed for a time of 1 minute to 20 minutes at a temperature of 20° C. to 30° C.

The second operation for thermal treatment of Step 385 may also simultaneously provide heat radiation through the supplementary heater 220 of FIG. 1. At this time, the electric power and the interval distance of the supplementary heater may be the same as the second operation for forming a layer of Step 360. Furthermore, the measuring of completeness of Step 390 is performed until the layers have reached a desired stage and then method 300 can be completed at Step 395.

Hereinafter, the present disclosure will be described in further detail with reference to accompanying examples. The following embodiments are only examples for understanding the present disclosure, and the range of the present disclosure is not limited to the same.

### <Example 1> Manufacture of Blank Mask Through Supplementary Heater 1

A light transmitting substrate made from quartz glass in the width of 6 inches, the length of 6 inches, and the thickness of 0.25 inches was disposed on a stage in a chamber of DC sputtering apparatus as an apparatus for forming a layer.

### 1. Forming Phase Shift Film in First Operation for Forming Layer

A target comprising a raw material in which molybdenum and silicon have been comprised in an atom ratio of 1:9 for molybdenum to silicon was disposed in a target unit, and at this time, the distance of 255 mm and the angle of 25 degrees were applied between the target and the light transmitting substrate. A magnetron capable of producing the magnetic field of 40 mT was disposed in the rear of the target of the target unit. An infrared heater as a supplementary heater was disposed in a position being distant by 100 mm from one side of the stage where the light transmitting substrate had been disposed.

An input gas having a ratio of 10:52:38 for argon:nitrogen:helium based on the volume was introduced into a chamber. Simultaneously, the electric power of 2.05 kW was applied, the rotation speed of the target unit was increased at a speed of 11 rpm per minute from initial 100 rpm to have 155 rpm, and the electric power of 0.5 W was applied to the infrared heater. The area to be formed was limited within an area set to have a size of 132 mm vertically and horizontally on the surface of the light transmitting substrate. The process for forming a layer was performed until a point at which the photon energy (PE) reached the value of 2.0 eV in a point having the Del_1 value of 0 according to Equation 1 below.

$$Del\_ 1 = {lim}_{Δ PE \to 0} ( \frac{Δ DPS}{Δ PE} ) \qquad [ Equation 1 ]$$

In the Equation 1, the DPS value is any one value between following i) and ii).

In the measurement for the surface of the phase shift film by a spectroscopic ellipsometer with an incident angle applied to be 64.5°, i) when the retardation between P wave and S wave of a reflection light is 180° or less, the DPS value is a retardation between the P wave and S wave, or ii) when the retardation between P wave and S wave of a reflection light is more than 180° or more, the DPS value is a value of subtracting the retardation between the P wave and S wave from 360°.

After the phase shift film was formed, heating was operated in a chamber maintained at the pressure of 1 Pa from 200° C. to 400° C. at the heating speed of 15° C./min, and thermal treatment was performed at this temperature for 30 minutes. Subsequently natural cooling was operated, and a nitrogen gas at 300° C. was put into the chamber for 30 minutes in the flow amount of 1 slm. During the thermal treatment, an electric power was applied to the supplementary heater under the condition proceeding in the process of forming a phase shift film.

a. Forming Light Shielding Film in Second Operation for Forming Layer

A laminate of the light transmitting substrate where the phase shift film had been formed was disposed in a chamber. A target comprising chrome was disposed in the target unit, and at this time, the distance of 280 mm and the angle of 25 degrees were applied between the target and the light transmitting substrate. A magnetron capable of producing the magnetic field of 40 mT was disposed in the rear of the target of the target unit. An infrared heater as a supplementary heater was disposed in a position being distant by 100 mm from one side of the stage.

### 2-1) Process of Forming Lower Layer of Light Shielding Film

An input gas having a ratio of 19:11:34:37 for argon:nitrogen:helium:carbon dioxide based on the volume was introduced into a chamber. Simultaneously, the electric power of 1.35 kW was applied, the rotation speed of the target unit was increased at the speed of 11 rpm per minute from initial 100 rpm to have 155 rpm, the rotation speed of the stage was also applied to be 10 rpm, and the electric power of 0.3 W was applied to an infrared heater. The process of forming a layer was performed until when the photon energy (PE) of an incident light reached the value of 2.0 eV in a point having the retardation of 140° between P wave and S wave measured by a spectroscopic ellipsometer.

### 2-2) Process of Forming Upper Layer of Shading Layer

An input gas having a ratio of 57:43 for argon:nitrogen based on the volume was introduced into a chamber. Simultaneously, the electric power of 1.85 kW was applied, the rotation speed of the target unit was increased at a speed of 11 rpm per minute from initial 100 rpm to have 155 rpm, the rotation speed of the stage was applied to be 10 rpm, and the electric power of 0.3 W was applied to an infrared heater. The process for forming a layer was performed until when the photon energy (PE) of an incident light in a point having the retardation of 140° between P wave and S wave measured by a spectroscopic ellipsometer.

After the light shielding film was formed, thermal treatment was performed for 15 minutes at 250° C., and cooling treatment was performed for 5 minutes at 25° C., thereby manufacturing a blank mask. During the thermal treatment, an electric power was applied to the supplementary heater under the condition proceeding in the process of forming a light shielding film.

### <Examples 2 to 6> Manufacture of Blank Mask Through Supplementary Heater: 2 to 6

In the formation of the phase shift film and the light shielding film of Example 1, the interval distance and the applied electric power of the infrared heater were changed as conditions of Table 1 below, the conditions excepting the above were the same as Example 1, and thereby blank masks of Examples 2 to 6 were manufactured.

### <Comparative Example 1> Manufacture of Blank Mask Excluding Supplementary Heater

In the formation of the phase shift film and the light shielding film of Example 1, the infrared heater was excluded, and the conditions excepting the above were the same as Example 1, and thereby a blank mask of Comparative Example 1 was manufactured.

TABLE 1

| | Electronic | Interval | Electronic | Electronic | Interval | Electronic |
|---|---|---|---|---|---|---|
| | Power of | Distance of | Power for | Power of | Distance of | Power for |
| | Supplementary | Supplementary | Sputtering | Supplementary | Supplementary | Sputtering |
| | Heater of | Heater of | of Phase | Heater of | Heater of | of Light |
| | Phase Shift | Phase Shift | Shift | Light | Light | shielding |
| Distinction | Film | Film | Film | shielding film | shielding film | film |
| Example 1 | 0.5 | 100 | 2.05 | 0.3 | 100 | 1.35 |
| Example 2 | 1.0 | 150 | 2.0 | 0.4 | 150 | 1.3 |
| Example 3 | 0.6 | 110 | 2.1 | 0.4 | 110 | 1.4 |
| Example 4 | 0.4 | 90 | 2.2 | 0.3 | 90 | 1.35 |
| Example 5 | 0.7 | 130 | 2.05 | 0.35 | 120 | 1.3 |
| Example 6 | 0.8 | 120 | 2.15 | 0.4 | 120 | 1.35 |
| Comparative | — | — | 2.05 | — | — | 1.35 |
| Example 1 | | | | | | |

Unit of Electric Power: kW
Unit of Interval Distance: mm

### <Experiment Example> Measurement of Rz, Rsk and Rku Roughness Values on Surface of Light Shielding Film

In the laminate of each blank mask measured from Examples 1 to 6 and Comparative Example 1, Rz, Rsk, Rku roughness values on the surface of a light shielding film were measured through a roughness meter (PPP-NCHR available from Park System corporation).

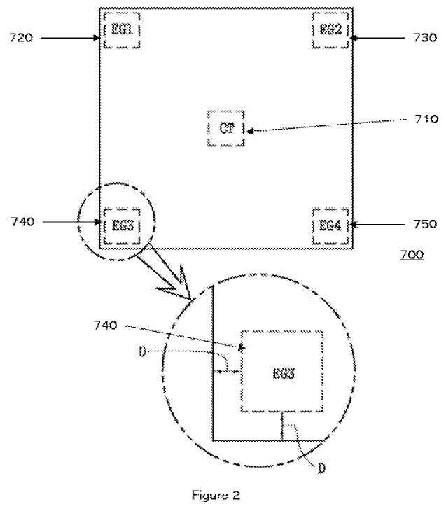

FIG. 2 illustrates an example of a laminate 700 according to one or more embodiments having a measuring area (CT) 710 in a center of the blank mask and measuring areas (EG1 to EG4) 720, 730, 740, and 750 being distant by a certain distance (D) from the edge.

As illustrated in FIG. 2, the CT 710 has a measuring area of 20 μm vertically and horizontally based on the center point of the light shielding film, and the measuring areas EG1 to EG4 720, 730, 740, and 750 are respectively distant by 20 mm from the four edges of the light shielding film in the quadrangle shape and respectively having a measuring area in the same size as the CT 710 were demarcated. In the respective measuring areas (CT and EG1 to EG4), respective roughness values were measured under the condition which was the scan speed of 0.5 Hz in a non-contact mode, and the result was shown in Tables 2 to 4.

TABLE 2

| Distinction by Rz | | | | | | | Absolute Value | *Percentage |
|---|---|---|---|---|---|---|---|---|
| Roughness of | | | | | | | of Difference | of Non- |
| Light shielding | | | | | | EG | between CT | uniformity |
| film | CT | EG1 | EG2 | EG3 | EG4 | Average | EG Average | (%) |
| Example 1 | 7.02 | 7.81 | 6.97 | 6.7 | 7.39 | 7.22 | 0.198 | 2.81 |
| Example 2 | 6.12 | 6.13 | 7.54 | 5.47 | 6.64 | 6.45 | 0.325 | 5.31 |
| Example 3 | 7.03 | 7.33 | 7.22 | 6.58 | 6.62 | 6.94 | 0.093 | 1.32 |
| Example 4 | 6.99 | 6.89 | 7.33 | 6.58 | 5.69 | 6.62 | 0.368 | 5.26 |
| Example 5 | 7.02 | 7.77 | 6.98 | 6.34 | 6.89 | 7.00 | 0.025 | 0.356 |
| Example 6 | 6.54 | 7.03 | 7.63 | 7.25 | 6.39 | 7.08 | 0.535 | 8.18 |
| Comparative | 7.02 | 9.23 | 9.33 | 9.65 | 9.26 | 9.37 | 2.35 | 33.4 |
| Example 1 | | | | | | | | |

Unit of Roughness: nm
*Percentage of Non-uniformity = {(Absolute Value of Difference between CT and EG Average)/CT} × 100%

TABLE 3

| | | | | | | | Absolute Value |
|---|---|---|---|---|---|---|---|
| Distinction by Rsk | | | | | | | of Difference |
| Roughness of | | | | | | | between |
| Light shielding | | | | | | EG | CT and EG |
| film | CT | EG1 | EG2 | EG3 | EG4 | Average | Average |
| Example 1 | −0.686 | −0.399 | −0.463 | −0.913 | −0.876 | −0.663 | 0.023 |
| Example 2 | −0.419 | −0.928 | −0.318 | −0.875 | −0.673 | −0.699 | 0.280 |
| Example 3 | −0.526 | −0.887 | −0.958 | −0.852 | −0.754 | −0.863 | 0.337 |
| Example 4 | −0.759 | −0.645 | −0.876 | −0.588 | −0.649 | −0.690 | 0.070 |
| Example 5 | −0.587 | −0.913 | −0.771 | −0.712 | −0.843 | −0.810 | 0.223 |
| Example 6 | −0.599 | −0.685 | −0.573 | −0.597 | −0.571 | −0.607 | 0.008 |
| Comparative | −0.658 | −1.235 | −1.293 | −1.254 | −1.385 | −1.292 | 0.634 |
| Example 1 | | | | | | | |

Unit of Roughness: nm
* Percentage of Non-uniformity = {(Absolute Value of Difference between CT and EG Average)/CT} × 100%

TABLE 4

| Distinction | | | | | | | Absolute | |
|---|---|---|---|---|---|---|---|---|
| by Rku | | | | | | | Value of | |
| Roughness | | | | | | | Difference | *Percentage |
| of Light | | | | | | | between CT | of Non- |
| shielding | | | | | | EG | and EG | uniformity |
| film | CT | EG1 | EG2 | EG3 | EG4 | Average | Average | (%) |
| Example 1 | 2.82 | 2.49 | 2.31 | 3.05 | 2.96 | 2.70 | 0.111 | 3.93 |
| Example 2 | 2.37 | 3.34 | 2.26 | 3.18 | 2.54 | 2.83 | 0.458 | 19.3 |
| Example 3 | 2.35 | 2.11 | 2.26 | 2.34 | 2.25 | 2.24 | 0.113 | 4.78 |
| Example 4 | 2.64 | 3.01 | 2.30 | 3.20 | 2.15 | 2.67 | 0.026 | 0.985 |
| Example 5 | 2.55 | 3.10 | 2.43 | 2.89 | 2.33 | 2.69 | 0.137 | 5.35 |
| Example 6 | 2.33 | 2.55 | 3.33 | 3.22 | 2.89 | 3.00 | 0.665 | 28.5 |
| Comparative | 2.33 | 4.21 | 4.01 | 4.32 | 4.34 | 4.22 | 1.89 | 81.1 |
| Example 1 | | | | | | | | |

Unit of Roughness: nm
*Percentage of Non-uniformity = {(Absolute Value of Difference between CT and EG Average)/CT} × 100%

With reference to the results of Tables 2 to 4, Examples manufactured through a supplementary heater were verified as having a small non-uniformity of Rz, Rsk and Rku roughness values between the center measuring area and the edge measuring area, while having a good roughness characteristic compared to Comparative Example.

### <Experiment Example> Measurement of Thickness and Optical Properties of Each Layer

In the laminate of each blank mask manufactured in Examples 1 to 6 and Comparative Example 1, for measuring thicknesses of a phase shift film and a light shielding film, a method as follows was performed.

As illustrated in FIG. 2, each laminate of Examples and Comparative Examples was demarcated into a CT 710 having a measuring area of 20 μm vertically and horizontally based on the center point of a light shielding film and EG1 to EG4 720, 730, 740, and 750 measuring areas being respectively distant by 20 mm from four edges of the light shielding film in a quadrangle shape and respectively having a measuring area in the same size as the CT.

A sample processed for respectively measuring areas to be cut (CT and EG1 to EG4) was prepared, the upper surface of the sample was treated by an ion beam, and the section of respective measuring areas (CT and EG1 to EG4) of the sample was taken into a photograph through Transmission Electron Microscope (JEM-2100F HR). Thicknesses of the light shielding film and the phase shift film layers were measured from the photographed image, and the result was shown in Tables 5 and 7.

In addition, from the laminate of each blank mask manufactured in Examples 1 to 6 and Comparative Example 1, optical density was measured for the respective measuring areas (CT and EG1 to EG4) of the light shielding film through a spectroscopic ellipsometer (MG-Pro available from Nano-View corporation), and the result was shown in Table 6.

Besides, in laminates whose manufacturing process had been formed to the formation of the phase shift film of Examples 1 to 6 and Comparative Example 1, CT having a measuring area of 20 μm vertically and horizontally based on the center point of the phase shift film, and EG1 to EG4 measuring areas being respectively distant by 20 mm from four edges of the phase shift film in a quadrangle shape and respectively having a measuring area in the same size as the CT were demarcated.

Through a retardation and transmittance meter (MG-Pro available from Nano-View corporation), transmittance and retardation were measured from respective measuring areas (CT, EG1 to EG4) of the phase shift film. In detail, a light irradiated the measuring area where the phase shift film had been formed and the light transmitting substrate where the phase shift film had not been formed, through ArF light source with the wavelength of 193 nm, difference values of retardation and transmittance between lights transmitting both areas were calculated, and the result was shown in Tables 8 and 9.

TABLE 5

| Distinction | | | | | | | Absolute | |
|---|---|---|---|---|---|---|---|---|
| by | | | | | | | Vale of | |
| Thickness | | | | | | | Difference | *Percentage |
| of Light | | | | | | | between | of Non- |
| shielding | | | | | | EG | CT and EG | uniformity |
| film | CT | EG1 | EG2 | EG3 | EG4 | Average | Average | (%) |
| Example 1 | 541.48 | 537.05 | 535.46 | 538.20 | 536.45 | 536.79 | 4.69 | 0.866 |
| Example 2 | 541.25 | 536.72 | 536.09 | 536.88 | 535.78 | 536.37 | 4.88 | 0.902 |
| Example 3 | 541.38 | 536.69 | 535.94 | 536.65 | 536.42 | 536.43 | 4.96 | 0.915 |
| Example 4 | 542.16 | 536.31 | 536.19 | 536.75 | 536.81 | 536.52 | 5.65 | 1.041 |
| Example 5 | 541.84 | 537.52 | 536.42 | 537.72 | 536.43 | 537.02 | 4.82 | 0.889 |
| Example 6 | 540.31 | 536.01 | 535.48 | 536.09 | 535.05 | 535.66 | 4.65 | 0.861 |
| Comparative | 539.27 | 524.27 | 528.58 | 519.59 | 523.53 | 523.99 | 15.3 | 2.833 |
| Example 1 | | | | | | | | |

Unit of Thickness: Ångström (Å)
*Percentage of Non-unif formity = {(Absolute Value of Difference between CT and EG Average)/CT} × 100%

TABLE 6

| | | | | | | | Absolute Vale | |
|---|---|---|---|---|---|---|---|---|
| Distinction by | | | | | | | of Difference | *Percentage |
| Optical Density | | | | | | | between | of Non- |
| of Light shielding | | | | | | EG | CT and EG | uniformity |
| film | CT | EG1 | EG2 | EG3 | EG4 | Average | Average | (%) |
| Example 1 | 1.83 | 1.81 | 1.83 | 1.81 | 1.83 | 1.82 | 0.010 | 0.546 |
| Example 2 | 1.8 | 1.78 | 1.78 | 1.78 | 1.80 | 1.79 | 0.015 | 0.833 |
| Example 3 | 1.8 | 1.78 | 1.77 | 1.78 | 1.79 | 1.78 | 0.020 | 1.111 |
| Example 4 | 1.78 | 1.75 | 1.78 | 1.79 | 1.79 | 1.78 | 0.002 | 0.140 |
| Example 5 | 1.78 | 1.75 | 1.76 | 1.76 | 1.76 | 1.76 | 0.023 | 1.264 |
| Example 6 | 1.76 | 1.75 | 1.77 | 1.76 | 1.76 | 1.76 | 0.000 | 0.000 |
| Comparative | 1.74 | 1.80 | 1.79 | 1.81 | 1.80 | 1.80 | 0.060 | 3.448 |
| Example 1 | | | | | | | | |

*Percentage of Non-uniformity = {(Absolute Value of Difference between CT and EG Average)/CT} × 100%

TABLE 7

| Distinction | | | | | | | Absolute Vale | |
|---|---|---|---|---|---|---|---|---|
| by | | | | | | | of Difference | *Percentage |
| Thickness | | | | | | | between CT | of Non- |
| of Phase | | | | | | EG | and EG | uniformity |
| Shift Film | CT | EG1 | EG2 | EG3 | EG4 | Average | Average | (%) |
| Example 1 | 690.93 | 686.97 | 684.93 | 687.29 | 685.81 | 686.25 | 4.68 | 0.677 |
| Example 2 | 690.87 | 687.42 | 686.32 | 686.06 | 685.43 | 686.31 | 4.56 | 0.660 |
| Example 3 | 691.27 | 686.87 | 686.80 | 685.90 | 686.79 | 686.59 | 4.68 | 0.677 |
| Example 4 | 691.25 | 686.53 | 686.42 | 685.66 | 686.89 | 686.38 | 4.88 | 0.705 |
| Example 5 | 691.25 | 687.31 | 685.74 | 687.17 | 685.73 | 686.49 | 4.76 | 0.689 |
| Example 6 | 691.55 | 687.58 | 687.10 | 686.95 | 685.98 | 686.90 | 4.65 | 0.672 |
| Comparative | 691.45 | 673.96 | 679.55 | 667.08 | 672.84 | 673.36 | 18.09 | 2.617 |
| Example 1 | | | | | | | | |

Unit of Thickness: Ångström (Å)
*Percentage of Non-uniformity = {(Absolute Value of Difference between CT and EG Average)/CT} × 100%

TABLE 8

| | | | | | | | Absolute | |
|---|---|---|---|---|---|---|---|---|
| | | | | | | | Vale of | |
| Distinction by | | | | | | | Difference | *Percentage |
| Transmittance | | | | | | | between | of Non- |
| of Phase | | | | | | EG | CT and EG | uniformity |
| Shift Film | CT | EG1 | EG2 | EG3 | EG4 | Average | Average | (%) |
| Example1 | 6.01 | 5.81 | 5.84 | 5.84 | 5.82 | 5.83 | 0.183 | 3.08 |
| Example2 | 6.09 | 5.82 | 5.82 | 5.81 | 5.84 | 5.82 | 0.268 | 4.39 |
| Examples | 6.01 | 5.80 | 5.82 | 5.83 | 5.79 | 5.81 | 0.200 | 3.33 |
| Example4 | 6.02 | 5.82 | 5.79 | 5.81 | 5.8 | 5.81 | 0.215 | 3.57 |
| Examples | 6.03 | 5.77 | 5.81 | 5.78 | 5.82 | 5.80 | 0.235 | 3.90 |
| Example6 | 6.10 | 5.80 | 5.83 | 5.84 | 5.84 | 5.83 | 0.273 | 4.47 |
| Comparative | 6.05 | 5.65 | 5.69 | 5.65 | 5.71 | 5.68 | 0.375 | 6.20 |
| Example 1 | | | | | | | | |

Unit of Transmittance: %
*Percentage of Non-uniformity = {(Absolute Value of Difference between CT and EG Average)/CT} × 100%

TABLE 9

| | | | | | | | Absolute | |
|---|---|---|---|---|---|---|---|---|
| Distinction | | | | | | | Vale of | |
| by | | | | | | | Difference | *Percentage |
| Retardation | | | | | | | between | of Non- |
| of Phase | | | | | | EG | CT and EG | uniformity |
| Shift Film | CT | EG1 | EG2 | EG3 | EG4 | Average | Average | (%) |
| Examplel | 175.37 | 174.87 | 174.35 | 174.93 | 174.55 | 174.68 | 0.695 | 0.396 |
| Example2 | 175.38 | 175.03 | 174.76 | 174.67 | 174.50 | 174.74 | 0.640 | 0.365 |
| Examples | 175.50 | 174.88 | 174.88 | 174.61 | 174.83 | 174.80 | 0.700 | 0.399 |
| Example4 | 175.49 | 174.75 | 174.79 | 174.55 | 174.85 | 174.74 | 0.755 | 0.430 |
| Examples | 175.45 | 175.00 | 174.60 | 174.94 | 174.57 | 174.78 | 0.673 | 0.383 |
| Examples | 175.50 | 175.02 | 174.89 | 174.85 | 174.60 | 174.84 | 0.660 | 0.376 |
| Comparative | 175.46 | 173.04 | 173.00 | 172.10 | 171.95 | 172.52 | 2.938 | 1.674 |
| Example 1 | | | | | | | | |

Unit of Retardation: °
*Percentage of Non-uniformity = {(Absolute Value of Difference between CT and EG Average)/CT} × 100%

With reference to the results of Tables 5 to 8, the light shielding film of Examples manufactured through a supplementary heater was verified as having a small non-uniformity of thickness and optical density between the center measuring area and the edge measuring area, while exhibiting good characteristics in the thickness and optical density compared to Comparative Example.

Additionally, the phase shift film of Examples manufactured through a supplementary heater was verified as having a small non-uniformity of thickness, transmittance, and retardation between the center measuring area and the edge measuring area, while exhibiting good characteristics in the thickness, transmittance, and retardation compared to the Comparative Example.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A blank mask, comprising:
a light transmitting substrate;
a light shielding film disposed on the light transmitting substrate; and
a phase shift film disposed between the light transmitting substrate and the light shielding film,
wherein the blank mask comprises a center measuring area based on a center of the light shielding film and an edge measuring area being distant by 20 mm from an edge of the light shielding film,
wherein the center measuring area and the edge measuring area are respectively squares having a side of 20 μm,
wherein the blank mask includes:
a center Rz roughness measured from the center measuring area,
an edge Rz roughness measured from the edge measuring area, and
an Rz roughness non-uniformity of 20% or less expressed by Equation 1-1 below:
Rz Roughness Non-uniformity=(Absolute Value of Difference between Center Rz Roughness and Edge Rz roughness/Center Rz Roughness)×100% [Equation 1-1].

2. The blank mask of claim 1, wherein the edge of the light shielding film is composed of four sides, and
wherein the edge measuring area comprises four edge measuring areas being distant in equivalent intervals from two sides among the four sides.

3. The blank mask of claim 1, wherein a center Rsk roughness is measured from the center measuring area,
wherein an edge Rsk roughness is measured from the edge measuring area, and
wherein an Rsk roughness difference of 0.5 nm or less is expressed by Equation 1-2 below:
Rsk Roughness Difference=(Absolute Value of Difference between Center Rsk Roughness and Edge Rsk Roughness) [Equation 1-2].

4. The blank mask of claim 1, wherein a center Rku roughness is measured from the center measuring area,
wherein an edge Rku roughness is measured from the edge measuring area, and
wherein an Rku roughness non-uniformity of 40% or less is expressed by Equation 1-3 below:
Rku Roughness Non-uniformity=(Absolute Value of Difference between Center Rku Roughness and Edge Rku Roughness/Center Rku Roughness)×100% [Equation 1-3].

5. The blank mask of claim 1, wherein the phase shift film comprises:
a second center measuring area based on the center of the phase shift film and a second edge measuring area being distant by 20 mm from the edge of the phase shift film,
a second center thickness measured from the second center measuring area,
a second edge thickness measured from the second edge measuring area, and
a thickness non-uniformity of 1.8% or less as expressed by Equation 2-1 below:
Thickness Non-uniformity=(Absolute Value of Difference between Second Center Thickness and Second Edge Thickness/Second Center Thickness)×100% [Equation 2-1].

6. The blank mask of claim 5, wherein the phase shift film comprises:
a second center transmittance measured from the second center measuring area;
a second edge transmittance measured from the second edge measuring area; and
a transmittance non-uniformity of 5.2% or less as expressed by Equation 2-2 below:
Transmittance Non-uniformity=(Absolute Value of Difference between Second Center Transmittance and Second Edge Transmittance/Second Center Transmittance)×100% [Equation 2-2].

7. The blank mask of claim 5, wherein the phase shift film comprises:
a second center retardation measured from the second center measuring area;
a second edge retardation measured from the second edge measuring area; and
a retardation non-uniformity of 1% or less as expressed by Equation 2-3 below:
Retardation Non-uniformity=(Absolute Value of Difference between Second Center Retardation and Second Edge Retardation/Second Center Retardation)×100% [Equation 2-3].

8. The blank mask of claim 1, wherein the light shielding film comprises:
a center thickness measured from the center measuring area;
an edge thickness measured from a second measuring area; and
a thickness non-uniformity of 2% or less as expressed by Equation 1-4 below:
Thickness Non-uniformity=(Absolute Value of Difference between Center Thickness and Edge Thickness Difference/Center Thickness)×100% [Equation 1-4].

9. The blank mask of claim 1, wherein the light shielding film comprises:
a center optical density measured from the center measuring area;
an edge optical density measured from the edge measuring area; and
an optical density non-uniformity of 2.7% or less expressed by Equation 1-5:
Optical Density Non-uniformity=(Absolute Value of Difference between Center Optical Density and Edge Optical Density/Center Optical Density)×100% [Equation 1-5].

10. An apparatus for forming a layer, comprising:
a chamber;
a stage in which a target substrate is placed inside the chamber;
a target unit comprising a raw material target for forming the target substrate; and
a supplementary heater disposed to have an interval from the stage for heating the target substrate.

11. The apparatus for forming a layer of claim 10, wherein the target unit is prepared to form the target substrate through a sputtering process,
wherein the supplementary heater is being distant by a value of 50 mm to 250 mm from a side of the stage, and
wherein the stage and the target unit are rotatable.

12. The apparatus for forming a layer of claim 11, wherein the sputtering process includes one of a direct current (DC) sputtering process or a radio frequency (RF) sputtering process.

13. The apparatus for forming a layer of claim 10, wherein the supplementary heater is configured to heat the target substrate on the stage through heat radiation.

14. A manufacturing method of a blank mask, comprising:
a first film formation operation of forming a phase shift film on a light transmitting substrate;
applying a first heating power by a supplementary heater to the phase shift film;
forming a light shielding film on the phase shift film; and
applying a second heating power by the supplementary heater to the light shielding film.

15. The manufacturing method of claim 14, wherein the first heating power includes an electric power of 0.3 kW to 1.5 kW, and
wherein the second heating power includes an electric power of 0.1 kW to 0.6 kW.

16. The manufacturing method of claim 14, wherein the target substrate comprises a light transmitting substrate.

17. The manufacturing method of claim 14, wherein the light forming substrate is provided on a stage inside a chamber of an apparatus configured to form layers, and
wherein the first film formation operation is performed by a target unit comprising a raw material target for forming the light transmitting substrate.
